(19) United States
(12) Patent Application Publication
(10) Pub. No.: US 2026/0147070 A1
(43) Pub. Date: May 28, 2026

(54) Three-Dimensional Magnetic Field Visualizer

(71) Applicant: Jon Bruce Davidson, Glendale, CA (US)

(72) Inventor: Jon Bruce Davidson, Glendale, CA (US)

(21) Appl. No.: 19/400,318

(22) Filed: Nov. 25, 2025

Related U.S. Application Data
(60) Provisional application No. 63/101,190, filed on Nov. 25, 2024.

(51) Int. Cl. G01R 33/10; G01R 33/032

(52) U.S. Cl. CPC G01R 33/10; G01R 33/032

(57) ABSTRACT

A device and a method are disclosed for visualizing a magnetic field in three dimensions. The device may include a top surface, outer wall, and an inner wall. A partition connects the outer wall and the inner wall. A visualization section is bounded by one side of the partition. A cavity is enclosed by the inner wall. An opening of the cavity is located through the top surface. The opening is configured to receive a magnet. The visualization section is sealed and includes containers and a liquid encasing the containers. Inside the containers are fluorescent-ferrous components that engage with a magnetic field and fluoresce when exposed to ultraviolet light.

### CROSS REFERENCE TO RELATED APPLICATIONS

This application claims the benefit of U.S. Provisional Application No. 63/101,190, filed Nov. 25, 2024, which is incorporated by reference.

### TECHNICAL FIELD

The disclosure generally relates to the field of scientific visualization tools, and more specifically, to a scientific visualization tool for magnetic field demonstration.

### BACKGROUND

Visualizing a magnetic field is important for explaining how the fundamental scientific phenomenon works in addition to promoting an interest in science, especially among children. While a computerized model or picture of a magnetic field may serve the purpose for teaching what a magnetic field looks like, these formats lack hands-on interaction that engages viewers and enables them to control the impact of a live magnetic field in front of them (e.g., by moving a magnet around and seeing how the magnetic field changes as the magnet moves). Conventional tools for visualizing a live magnetic field range from simply using iron filings on a sheet of paper over a magnet to more complex and abstract tools for viewing effects of a magnetic field such as ferrofluid. However, conventional tools are challenged to both show pole-to-pole lines of a live magnetic field and, critically, show that field in three dimensions.

### SUMMARY

A three-dimensional (3D) magnetic field visualizer is a tool to visualize a magnetic field in three dimensions.

Conventional tools like using iron filings or a compass array can only show a magnetic field in two dimensions. While ferrofluids can form 3D structures that illustrate the impact of a magnetic field, they do not provide a clear visualization of the field lines that go from pole-to-pole of the magnetic field. Thus, ferrofluids are less than ideal for explaining the underlying scientific principles.

Various disclosed 3D magnetic field visualizers enable visualization of the shape of a live magnetic field. Further, the visualization occurs in three dimensions, not simply two. The visualizers may be fully contained such that minimal to no cleanup is required, which is useful for using the visualizer with children who need supervision with more complicated or messier tools. Optionally, the visualizers may operate without a power source (e.g., when a reset mechanism powered by an electromagnet is omitted from a visualizer).

In a first example of a 3D magnetic field visualizer, the visualizer is a container having stackable plates, each plate having an array of concave cavities. Inside each cavity may be an oblong or capsule-shaped fluorescent object that is ferrous at one end. The cavities provide space for each capsule to move around. Specifically, each capsule has space to move and orient itself along directions of a magnetic field of a magnet (e.g., when a user inserts the magnet into a cavity in the container). The plates may be encased by a liquid within the container. The same liquid may be in each cavity or encasing the plates. The plates may include through holes that reduce the pressure exerted by the liquid on the plates and allow the plates to maintain contact with one another. The outer wall of the visualizer, the plates, and the liquid may have substantially the same refractive indices for light generated by the fluorescent-ferrous components such that the view of the capsules is clear through the outer wall of the visualizer, the plates, or the liquid.

In a second example of a 3D magnetic field visualizer, the visualizer is a container having tubes containing components that are spherical in shape, where the container and the rods are filled with a fluid. Inside the spheres are fluorescent rods with a ferrous ball at one end of the rods. A cavity within the visualizer provides a path for a magnet to move surrounded by the sphere-filled rods. As a magnet moves within the cavity and as ultraviolet (UV) light is applied to the spheres, a user can visualize lines of the magnet's magnetic field, which is represented by the fluorescent rods that align with the magnetic field lines. The rods align when the magnetic field and the ferrous balls interact, causing the respective spheres to rotate themselves to align with the magnetic field.

In a third example of a 3D magnetic field visualizer, the visualizer is a container having ferromagnetic particles suspended within liquid-filled tubes inside the container. The particles are coated with a fluorescent pigment. A cavity within the visualizer provides a path for a magnet to move surrounded by the particles. As the container is rotated while a magnet is within the cavity and the particles are exposed to UV light, the particles that travel within each tube may be suspended or held in place due to the pull from the magnet's magnetic field. The fluorescence of the suspended particles may form the shape of the magnet's magnetic field.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

FIGS. 1A-1C illustrate a three-dimensional (3D) magnetic field visualizer, in accordance with one embodiment.

FIG. 2A shows a vertical cross section of a visualizer, in accordance with one embodiment.

FIG. 2B shows a horizontal cross section of the visualizer of FIG. 2A, in accordance with one embodiment.

FIG. 3 depicts a tube containing fluorescent-ferrous components, in accordance with one embodiment.

FIG. 4 shows one of the fluorescent-ferrous components of FIG. 3, in accordance with one embodiment.

FIGS. 5A-5C illustrate a 3D magnetic field visualizer using ferromagnetic particles, in accordance with one embodiment.

FIG. 6A shows two plates of a visualizer having fluorescent-ferrous components oriented along a common orientation, in accordance with one embodiment.

FIG. 6B shows the two plates of FIG. 6A having fluorescent-ferrous components oriented along a magnetic field of a magnet, in accordance with one embodiment.

FIG. 7 shows stacked plates of a 3D magnetic field visualizer, in accordance with one embodiment.

FIG. 8 is a flowchart depicting a process for operating a 3D magnetic field visualizer, in accordance with one embodiment.

### DETAILED DESCRIPTION

The Figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

### Configuration Overview

The three-dimensional (3D) magnetic field visualizer, “visualizer,” described here is an interactive magnetic field viewer that safely displays the alignment of ferrous components in response to magnetic forces, allowing for clean and reusable demonstrations. The visualizer is enclosed (i.e., the ferrous components are contained within the visualizer) to improve the ease in which the tool can be reused and minimize clean up after demonstrations.

A combination of ultraviolet (UV), fluorescent and ferrous components, and a magnet are used by a 3D magnetic field visualizer to allow users to see lines of a magnetic field of the magnet. A visualizer contains the fluorescent and ferrous components, which may be referred to as fluorescent-ferrous components, that fluoresce when exposed to a UV light. These components may have fluorescent pigments coating a particular shape or marking that when proximate to a magnetic field, orient in a direction reflecting a direction of the magnetic field.

In one example of operating a visualizer, polarized UV light strikes the visualizer from behind, above, and below. Terms such as “behind,” “top,” “above,” “bottom,” “below,” “front,” and “back” are used for convenience and should not require a particular orientation of the visualizer. The front of the visualizer may be covered with a polarizing filter having an orientation of ninety degrees difference from the orientation of the polarized UV light striking the visualizer. In this way, the UV light does not go through the front of the visualizer where it may enter the user's eyes, consequently, damage to the eyes of the user by the UV light may be avoided. Further, certain UV light sources may include a visible light component (e.g., blue light) that enables the user to visualize when the UV light is on or off. With these types of UV light sources, the polarizing filter may also improve the visibility of the contents of the visualizer by reducing the intensity of the visible light component of the UV light source that passes through the polarizing filter. The UV light will penetrate the visualizer to strike the fluorescent-ferrous components within the visualizer.

In this first example, the fluorescent-ferrous components may be oriented in a single direction or substantially the same direction during an initialization stage, which may also be referred to as a reset stage. In the initialization stage, a magnet may be absent from a cavity inside the visualizer. Instead, one or more electromagnets may be used to align or re-align the fluorescent-ferrous components to substantially the same direction. In the initialization stage, the visualizer is not necessarily exposed to a UV light, but if there is UV light exposure, the user may see the fluorescence of the fluorescent-ferrous components forming approximately straight lines in a single direction.

As a magnet is positioned proximate to the fluorescent-ferrous components, the fluorescent-ferrous components will reorient themselves because the ferrous material engages with the magnetic field of the magnet. As the moving fluorescent-ferrous components are exposed to UV light, the fluorescence coming off the fluorescent-ferrous components forms a visual of the magnetic field lines of the magnet. Thus, a user of the visualizer can visualize a magnetic field in 3D.

In a second example of operating a visualizer, UV light strikes a visualizer containing fluorescent-ferrous components. In this example, the UV light is not necessarily polarized. The fluorescent-ferrous components may be fluorescent pigment-coated and ferromagnetic particles. In an initialization stage where a magnet is not proximate to the fluorescent-ferrous components, the fluorescent-ferrous components may be located at the bottom of the visualizer due to the force of gravity. As a magnet is positioned proximate to the fluorescent-ferrous components within the visualizer, the fluorescent-ferrous components are held aloft by the force of the magnetic field. The fluorescent-ferrous components will fluoresce and their luminance will represent the shape of the magnetic field.

### Visualizer with Microspheres

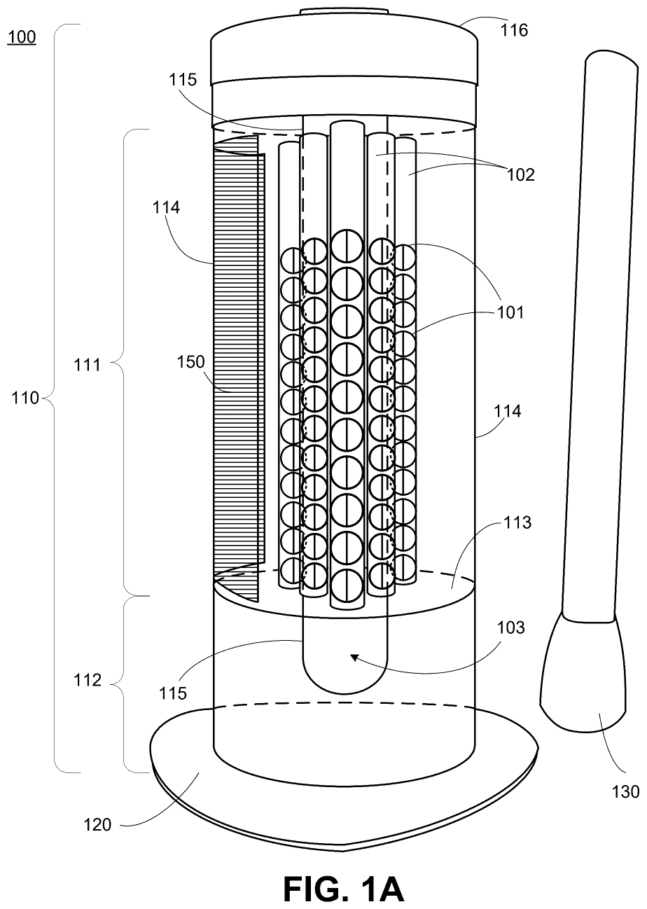

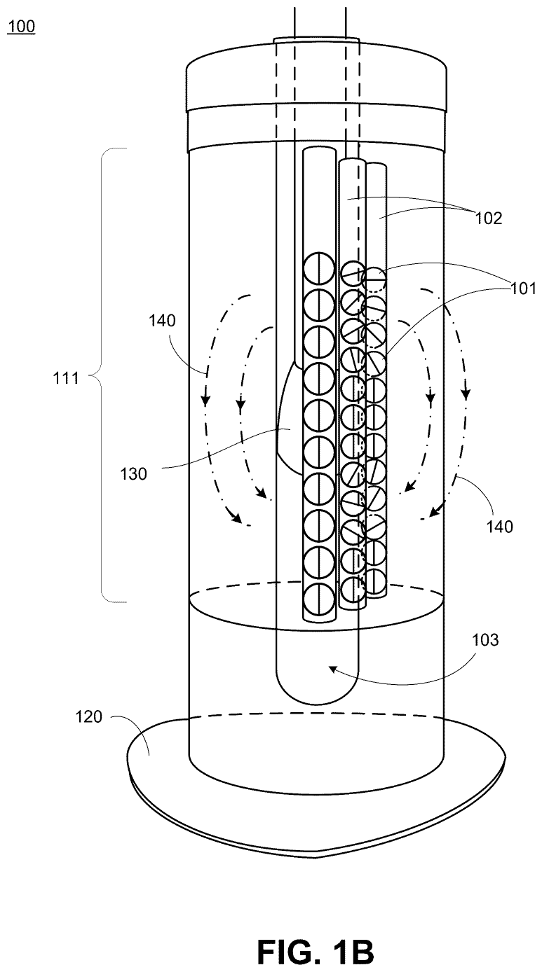

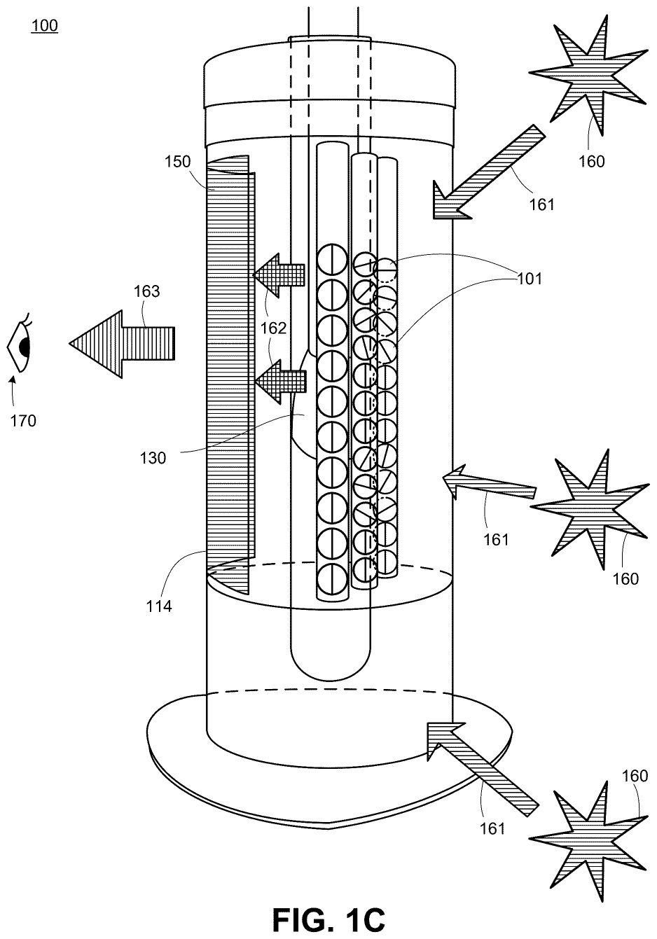

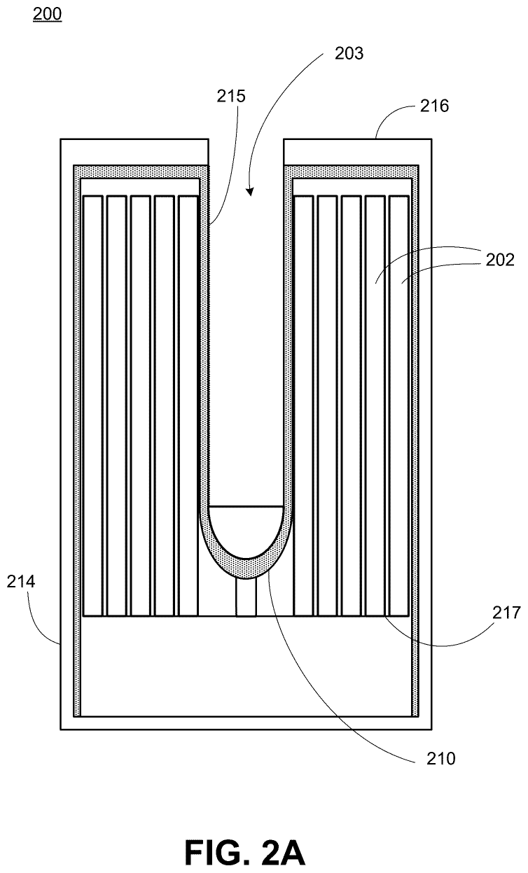

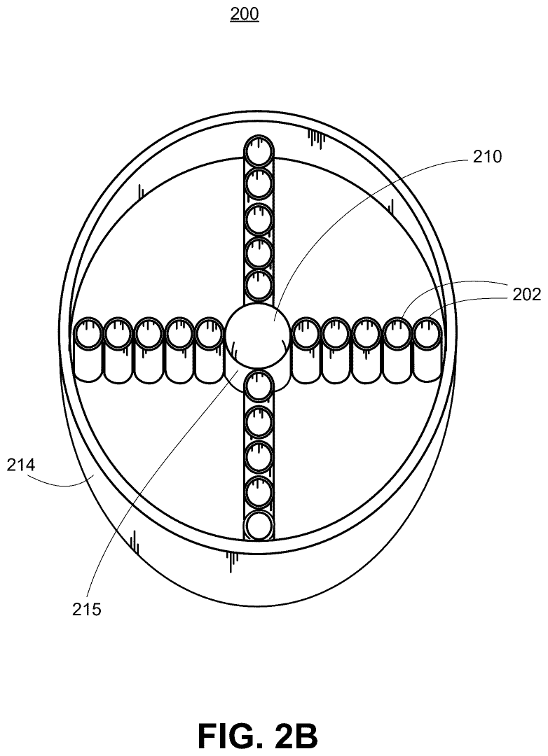

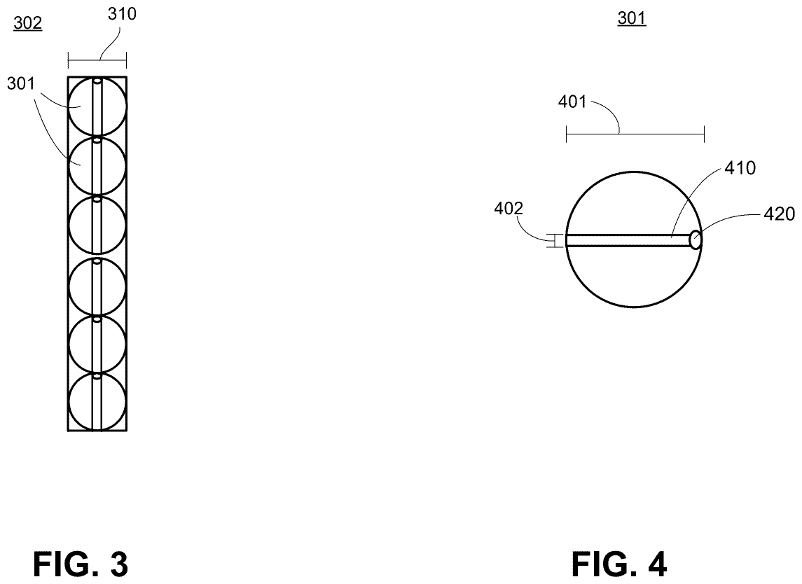

Referring now to FIGS. 1A through 4, illustrated are embodiments of a three-dimensional (3D) magnetic field visualizer for visualizing three dimensions of a magnetic field using tubes of spherical fluorescent-ferrous components (e.g., beads). A full view of an example of the visualizer during operation is shown in FIGS. 1A-1C. Cross sections of the inside of an example visualizer from various angles are shown in FIGS. 2A and 2B. The tubes and beads within a visualizer are depicted in FIGS. 3 and 4.

FIGS. 1A-1C illustrate a 3D magnetic field visualizer 100, in accordance with one embodiment. FIG. 1A shows the visualizer 100 during an initialization or reset stage where a magnet 130 is not proximate to fluorescent and ferrous components for visualizing the magnetic field of the magnet. FIGS. 1B and 1C show the visualizer 100 during a visualization stage where the magnet 130 is inserted into the visualizer 100. The following description will first describe the components of the visualizer 100 followed by an example process of resetting and using the visualizer 100.

The visualizer 100 may be a cylindrical container having fluorescent and ferrous components 101, referred to as “fluorescent-ferrous components,” that enable a user to visualize the lines of a magnetic field when the magnet 130 is proximate to the fluorescent-ferrous components 101. The visualizer 100 may include a container 110 and a base 120. The base 120 may be a flat surface on which the container 110 is supported upright. The container 110 may include a visualization section 111 and a reset section 112 partitioned by a partition 113. The reset section 112 may include one or more electromagnets, a power source for the electromagnet(s), or both. The container 110 is depicted as cylindrical but may be a different shape (e.g., rectangular, spherical, triangular, or any suitable shape). The container 110 may have an outer wall 114, an inner wall 115, and a top surface 116. The outer wall 114 is exposed to the environment and contactable by a user.

The inner wall separates a liquid held within the visualization section 111 of the container 110 from a cavity 103 in which the magnet 130 may be positioned. The visualization section 111 is sealed such that the liquid is contained. The liquid may be an oil, mineral oil, water, or other fluid having a refraction index that substantially matches the refractive index or indices of components of the visualizer through which light emitting from the fluorescent-ferrous components 101 travels (i.e., for the wavelength of light emitting by the fluorescent-ferrous components 101). The similarity in refractive index promotes the visibility of the fluorescence of the fluorescent-ferrous components 101. In some embodiments, the cavity 103 may also contain the liquid, which may reduce reflections of the fluorescence against the walls of the cavity 103 that may interfere with the visibility of the fluorescent-ferrous components 101 (e.g., reducing the crispness of the light from the fluorescent-ferrous components 101 that would otherwise show the direction of a magnetic field of a magnet inside the cavity 103). In these embodiments, the visualizer 100 may further include a cover configured to be received by the cavity 103 to provide containment for the liquid inside the cavity 103 (e.g., when the magnet is not inserted into the cavity 103). It should be appreciated that a range of techniques may be used for refractive index matching or approximate matching at material interfaces to reduce refraction of light leaving the visualizer 100.

The visualization section 111 contains components for visualizing a magnetic field of a magnet within the cavity 103 (e.g., the magnetic field of the magnet 130 when inserted into the visualizer 100). The magnet may be a permanent magnet, electromagnet, temporary magnet, or any other type of object that generates a magnetic field within the visualizer. In some embodiments, multiple magnets may be inserted into a visualizer (e.g., for viewing the magnetic field lines produced by two proximate magnets). Components include the fluorescent-ferrous components 101 and the tubes 102. In some embodiments, the visualization section 111 may include a magnet (e.g., where the magnet is affixed to the visualizer rather than a separately insertable component). A polarizing screen 150 may be affixed to a portion of the outer wall 114 or manufactured into the outer wall of the visualizer 100 around the visualization section 111. In some embodiments, a UV light may be located within the visualizer 100. In these embodiments, the visualizer 100 may include a mechanism for adjusting the polarizing angle of the UV light within the visualizer 100. For example, the UV light may be coupled to a motorized actuator or other adjustment mechanism that allows a user to control the direction of the UV light. The transmission axis of the polarization screen 150 may be orthogonal (i.e., approximately ninety degrees) to the polarization direction of the UV light to which it is exposed. In this way, users can see the fluorescence from the fluorescent-ferrous components 101 with less interference from the UV light source used to create that fluorescence.

The reset section 112 contains components for resetting or re-initializing the fluorescent-ferrous components 101. In one embodiment, the reset section 112 includes an electromagnet and a battery. Additionally or alternatively, there may be an external power source coupled to the electromagnet (e.g., to connect the visualizer to a power outlet). In response to one or more electromagnets being switched on and a magnet being positioned away from the fluorescent-ferrous components (e.g., removed from the cavity 103), the reset stage may be triggered to reset the fluorescent-ferrous components 101. During the reset stage, the electromagnet causes the fluorescent-ferrous components 101 to align in substantially the same direction.

In an alternative embodiment, the reset section 112 includes multiple electromagnets. For example, the reset section 112 may include a first electromagnet towards the base of the device, similar to the embodiment of the reset section 112, and a second electromagnet that is movable along an outer surface of the visualizer 100. The second electromagnet may be a ring electromagnet having a diameter greater than the container 110. As the second electromagnet moves from one end of the container 110 (e.g., the top) to the other end of the container 110 (e.g., the bottom), the fluorescent-ferrous components 101 may reorient themselves in response to the magnetic field of the second electromagnet. Once the second electromagnet has traveled to the other end of the container 110, the fluorescent-ferrous components 101 may align in substantially the same direction. After the second electromagnet is turned off, the first electromagnet may be turned on to provide additional magnetic force to augment the reorienting effect of the first and second electromagnets on the fluorescent-ferrous components 101. The first and second electromagnets may operate nonconcurrently so as to avoid affecting each other's performance. For example, the second electromagnet may turn off as it nears the bottom of the container 110 and in response, the first electromagnet may turn on, completing orientation of the fluorescent-ferrous components 101 in a vertical alignment.

In yet another embodiment of a reset section, the reset section may include a single, movable ring electromagnet as described previously, without an electromagnet located towards the base of the device.

In response to the electromagnet(s) being switched off and a magnet being positioned proximate to the fluorescent-ferrous components (e.g., inserted into the cavity 103), a visualization stage may begin. During the visualization stage, the fluorescent-ferrous components 101 engage with the magnetic field of a magnet and fluoresce in response to UV exposure from UV light sources 160 (e.g., as depicted in FIG. 1C).

In alternative embodiments, the visualizer 100 does not include a reset section 112. In such embodiments, the reset stage may be performed without the reset section 112. In one example, the reset stage may be performed by shaking the visualizer 100. In another example, the reset stage may be performed automatically when no magnet(s) are proximate to the fluorescent-ferrous components 101 and the weight of a relatively heavier area within each of the fluorescent-ferrous components 101 may naturally cause the fluorescent-ferrous components 101 to orient themselves a certain direction with the heavier area facing downwards as a natural effect of gravitational forces. In yet another example, the reset stage may be performed using an external magnet (e.g., a magnet that is not affixed to the visualizer 100 and is positioned by the user at one side of the visualizer 100).

The fluorescent-ferrous components 101 may be spherical in shape (e.g., a clear microsphere) and hold a rod comprising fluorescent material. A ball of ferrous material is located at one end of each rod. Embodiments of the rods comprising the fluorescent material include both a surface layer (e.g., a fluorescent coating) of the fluorescent material or the entire structure (e.g., as a base material) formed in whole or in part of the fluorescent material. In one example of a fluorescent material, the composition of the rods can include flavins or azaaromatic organic molecules which may fluoresce more brightly in a magnetic field. In another example of a fluorescent material, the composition of the rods can include a crystalline lattice fluorescent material for which fluorescence is dependent on the polarization of the incident UV light,. In certain orientations, rods including the crystalline lattice fluorescent material may fluoresce more brightly than in other orientations. Where the rods are composed of a material that may fluoresce and exhibit polarizing characteristics such as the crystalline lattice fluorescent material, a polarizing screen may be omitted from the visualizer 100. In a third example of a fluorescent material, the rods may be comprised of a tetracene crystal.

In some embodiments, rods within the fluorescent-ferrous components 101 may be polarized. For example, the surface of a rod may be covered in a polarizing film. Where the rods are polarized, a polarizing screen (e.g., the polarizing screen 150) may be omitted from the visualizer 100. A polarized UV light source may be directed at the fluorescent-ferrous components 101, and the polarizing film at each of the rods may serve the function of the polarizing screen 150 in reducing the harmful UV light that is directed at a user's eyes. Further, a subset of the polarized rods may not fluoresce when exposed to a polarized UV light source having light polarized orthogonal to the polarization of the subset of the rods. For example, the rods that remain vertical after being reset by an electromagnet and are not reoriented (e.g., because they are unaffected by a subsequently introduced magnetic field) may not fluoresce because their polarization film blocks the polarized UV light from interacting with the fluorescent coating of the rods underneath the polarizing film.

Polarizing films or polarizing screens may be omitted from the visualizer 100. Instead, an unpolarized UV light source may be used to illuminate fluorescent-ferrous components 101. Some of the fluorescent-ferrous components 101 may remain in an initial orientation and be unaffected by a proximal magnetic source (e.g., due to variations in ferrous mass, geometry, or magnetic susceptibility). In such embodiments, visibility of magnetically unaffected fluorescent-ferrous components 101 may be reduced through selection of fluorescent materials that emit increased fluorescence in the presence of a magnetic field (e.g., azaaromatic organic molecules), or by directing the UV light source(s) primarily toward regions influenced by a magnetic field.

In some embodiments, a polarized ultraviolet light source is employed in conjunction with a front polarizing screen (e.g., the polarizing screen 150) oriented orthogonal to the polarization of the UV light. The front polarizing screen may be included to attenuate or block directly transmitted light from the UV light source (e.g., visible blue light), which may improve the viewing contrast of the fluorescent-ferrous components 101 influenced by a magnetic field. Certain fluorescent materials, when excited by polarized UV light, may emit repolarized fluorescent light having the same orientation as the incident light. This effect can reduce visibility of the desired fluorescence when a front polarizer is used. When the fluorescent material of the rods exhibits negligible repolarization, such an arrangement may effectively reduce visible blue light from the UV source while maintaining visibility of fluorescence from magnetically affected rods.

The fluorescent-ferrous components 101 may be housed within tubes 102. The tubes 102 may be clear. The tubes 102 may have a refractive index substantially matching the refractive index of the fluorescent-ferrous components 101 and the liquid within the container 110. The tubes 102 may be positioned around the cavity 103. Although the tubes 102 are depicted as being aligned along the same direction as the length of the container 110, the tubes 102 may be structured in alternative directions (e.g., horizontally, curved, rings, coils, etc.) that support the positioning of the fluorescent-ferrous components 101 near the cavity 103. The tubes 102 are further described with respect to FIG. 3 and the fluorescent-ferrous components 101 are further described with respect to FIG. 4.

The cavity 103 is structured to enable a magnet to move within the cavity 103 and engage with the fluorescent-ferrous components 101 on the other side of the inner wall 115. The cavity 103 is enclosed by the inner wall 115. The visualizer 100 may receive a magnet through the opening of the cavity 103. The opening through which the magnet 130 may be inserted may be located through the top surface 116 of the visualizer 100. The cavity 103 may extend through the visualization section 111 and into the reset section 112. In some embodiments, the cavity 103 extends only through the visualization section 111 and not into the reset section 112. The width of the cavity 103 may be approximately one third of the width of the visualizer 100. Although the cavity 103 is depicted as having a uniform width along its length, alternative embodiments of the cavity 103 may include tapering or widening width along its length. Varying widths may enable users more degrees of freedom to move a magnet within the visualizer 100 and to see variations of interaction between a magnet and the fluorescent-ferrous components.

The magnet 130 is depicted as detached from the visualizer 100, but in alternative embodiments, a magnet may be affixed within the visualizer 100. In some embodiments, a magnet may be coupled to a pulley system, slide mechanism, rack and pinion system, a motorized linear actuator, or any suitable mechanism for controlling movement of a magnet along a path proximate to fluorescent-ferrous components within a visualizer (e.g., a path within the cavity 103).

Although not depicted, the visualizer 100 may include a battery or a connection to an external power source. The battery or external power source may be electrically coupled to an electromagnet used during the reset stage. Additionally, the visualizer 100 may include a UV-coating at the surface of the visualizer section 111 to protect the user's eyes from UV light exposure. In some embodiments, where the UV coating is included, the polarizing screen 150 may optionally be omitted, the light source may be a non-polarized UV light, or a combination thereof. Additionally or alternatively to the UV coating, a spectral filter may be positioned proximate to the UV light source 160. One example of a spectral filter is a crystal ultraviolet filter configured to block visible blue light while transmitting UV light. The crystal filter may reduce viewer exposure to UV light and minimize visible blue light emission.

During a reset stage depicted in FIG. 1A, the magnet 130 is not inserted into the visualizer 100 and the fluorescent-ferrous components 101 are oriented in substantially the same direction. During the visualization stage depicted in FIGS. 1B and 1C, the magnet 130 is inserted into the visualizer 100 and the fluorescent-ferrous components 101 re-orient themselves under the influence of the magnetic field 140 of the magnet 130. For example, a ferrous ball within a fluorescent-ferrous component engages with a magnetic field, and this engagement causes a rod coated with fluorescent pigment that is attached to the ferrous ball to re-orient itself such that the rod is aligned with a line of the magnetic field 140.

Further during the visualization stage, one or more UV light sources 160 direct polarized UV light 161 at the fluorescent-ferrous components 101. In some embodiments, the UV light sources 160 are positioned to direct illumination from above or below the visualizer 100, rather than from the front. This may reduce the likelihood that UV light is emitted along a line of sight toward a user's eyes when the visualizer 100 is viewed from the side. Moreover, directing UV illumination from above or below the fluorescent-ferrous components 101 may provide an alternative to the use of individual polarizing films on the fluorescent-ferrous components 101 (e.g., films on the rods). By adjusting the size and position of a UV illumination zone, fluorescent-ferrous components 101 located in a region influenced by a magnetic field may be selectively illuminated. In this way, illumination from above or below allows fluorescence from magnetically affected vertical rods to remain visible, while rods outside the affected area may remain unilluminated and do not detract from the magnetic field visualization.

In response to the UV light exposure, the fluorescent-ferrous components 101 fluoresce and emit light 162. The light 162 exits the visualizer 100 through the clear exterior of the visualization section 111 (i.e., through the outer wall 114). Specifically, when the light 162 exits the portion of the outer wall 114 to which the polarizing screen 150 is affixed, a user 170 sees light from a portion of the light 162 but not the polarized UV light 161 because the polarization screen 150 filters out the polarized UV light 161. This may protect the user's eyes from harmful UV light exposure. The lights 161, 162, and 163 are represented by arrows having stippling that is vertical, horizontal, or a combination of both to represent the orientation of the light (e.g., the light 161 is polarized orthogonally to the light 163).

For clarity, a subset of the tubes 102 depicted in FIG. 1A have been omitted from FIGS. 1B and 1C so that the magnet 130 within the cavity 103 may be more easily viewed. The fluorescent-ferrous components 101 within the omitted tubes can also reorient themselves according to the magnetic field 140 of the magnet 130. Additionally, the polarizing screen 150 has been omitted from FIG. 1B so that the magnetic field 140 may be more easily viewed. Further, the magnetic field 140 has been omitted from FIG. 1C so that the polarizing screen 150 may be more easily viewed.

FIG. 2A shows a vertical cross section of visualizer 200, in accordance with one embodiment. The cross section is taken orthogonal to the base of the visualizer 200, viewed from the side of the visualizer 200. The visualizer 200 includes a top surface 216 in addition to the outer wall 214 and an inner wall 215. The cross section depicts a visualization section of the visualizer 200. The visualization section is bounded by the outer wall 214, the inner wall 215, the top surface 216, and a partition. A cavity 203 is located at approximately the center of the visualizer 200. The bottom 210 of the cavity 203 is depicted as being at a different height within the visualizer 200 than one end of tubes 202; However, in alternative embodiments, the bottom 210 of the cavity 203 may be level with one end of the tubes 202. The tubes 202 may contact a partition 217 of the visualizer 200 at one end of the tubes 202. In alternative embodiments, the ends of the tubes 202 may not contact a surface of the visualizer 200. Instead, the sides of the tubes 202 may contact one or more of the inner wall 215 or another tube such that each tube maintains a fixed position within the visualizer 200. The tubes 202 may contact the visualizer 200 at both ends of the tubes 202, at only one end, or at no end.

FIG. 2B shows a horizontal cross section of a visualizer 200, in accordance with one embodiment. The cross section is taken parallel to the base of the visualizer 200, viewed from below the visualizer (e.g., facing towards a top surface of the visualizer). The tubes 202 are arranged in an X-shape within the visualization section. The apparent intersection of the lines of tubes 202 is the center of the cavity. One of the tubes 202 contacts the inner wall 214 and other tubes may contact at least one other tube. The placement of the tubes 202 may be in lines such that the tubes within each line are placed contiguously or substantially contiguously (e.g., a space between two tubes that is less than 10% of the diameter of a tube). Although the tubes 202 are placed in an X-shape, the placement of tubes containing fluorescent-ferrous components may be any suitable arrangement for viewing. For example, the tubes 202 may be placed in rings centered around the cavity or around a subsection of the visualization section (e.g., a quarter-circle).

FIG. 3 depicts a tube 302 containing fluorescent-ferrous components 301, in accordance with one embodiment. The tube 302 may be one embodiment of the tubes 102 of FIG. 1. The tube 302 may be composed of one of a borosilicate or polyacrylate (e.g., a clear glass or plastic). Within the tube 302 are one or more of the fluorescent-ferrous components 301. The number of fluorescent-ferrous components 301 placed into each tube 302 may be such that the fluorescent-ferrous components 301 are contiguous or non-contiguous. Contiguous placement causes each fluorescent-ferrous component 301 to contact at least one other fluorescent-ferrous component 301 when the visualizer is positioned on its side (i.e., gravitational forces do not cause one fluorescent-ferrous component 301 to contact another fluorescent-ferrous component 301 below it). Non-contiguous placement enables each fluorescent-ferrous component 301 to be more easily movable (e.g., laterally in addition to rotationally) within the tubes 302. The diameter 310 of each tube may range from 0.1 mm to 3 mm.

FIG. 4 shows one of the fluorescent-ferrous components 301 of FIG. 3, in accordance with one embodiment. The fluorescent-ferrous component 301 may be one embodiment of the fluorescent-ferrous components 101 of FIG. 1. The fluorescent-ferrous component 301 is depicted as being spherical in shape (e.g., a bead), but in alternative embodiments, may be any shape suitable for rotation among other fluorescent-ferrous components. The fluorescent-ferrous components 301 may be composed of one of a borosilicate or polyacrylate. The fluorescent-ferrous component 301 may have a width 401 ranging from 0.01 mm to 2 mm (e.g., a sphere having a diameter of 1 mm). Within the fluorescent-ferrous component 301 are a fluorescent component 410 and a ferrous component 420.

The fluorescent component 410 may be a rod, filament, fiber, or any suitable structure that may be coated with a fluorescent pigment to form a line or an approximate line such that the structure may align with a magnetic field line. In one embodiment, the fluorescent component 410 may be composed of additional smaller components forming a substantially linear structure (e.g., a fluorescent powder that is encapsulated into a hollow tube within the fluorescent-ferrous component). In another embodiment, the fluorescent component 410 may be a fluorescent coating of an inner wall of a linear cavity (e.g., a hollow tube) within the fluorescent-ferrous component. The fluorescent component 410 may be composed of a clear material (e.g., plastic). The fluorescent component 410 may have a width 402 of approximately 5-10% of the width 401 of the fluorescent-ferrous component and a length that is shorter than or approximately equal to the width 401 of the fluorescent-ferrous component. For example, the length of a fluorescent rod within a spherical fluorescent-ferrous component may have a length that is less than but approximately the diameter of the sphere to account for the ferrous component 420 at the end of the rod.

The ferrous component 420 engages with a magnet in its proximity to cause the fluorescent-ferrous component 301 to orient itself based on the magnet's magnetic field (e.g., based on the distance between the ferrous component 420 and the magnet, the magnetic field strength of the magnet, etc.). The ferrous component 420 is a magnetic material located near the outer wall of the fluorescent-ferrous component 301 (e.g., a ferromagnetic tip of a fluorescent rod). In one example, the ferrous component 420 may be a ferromagnetic ball of iron or other magnetic material. The ferrous component 420 may be contained within each fluorescent-ferrous component 301 or a portion of the ferrous component 420 may form part of the surface of the fluorescent-ferrous component 301 (e.g., the ferrous component 420 is a ball of iron that is located at the outer wall of the fluorescent-ferrous component 301 such that part of the iron ball's surface forms part of the surface of the fluorescent-ferrous component 301). The volume of the ferrous component 420 may be approximately 1-5% of the volume the fluorescent-ferrous component 301.

### Visualizer with Ferromagnetic

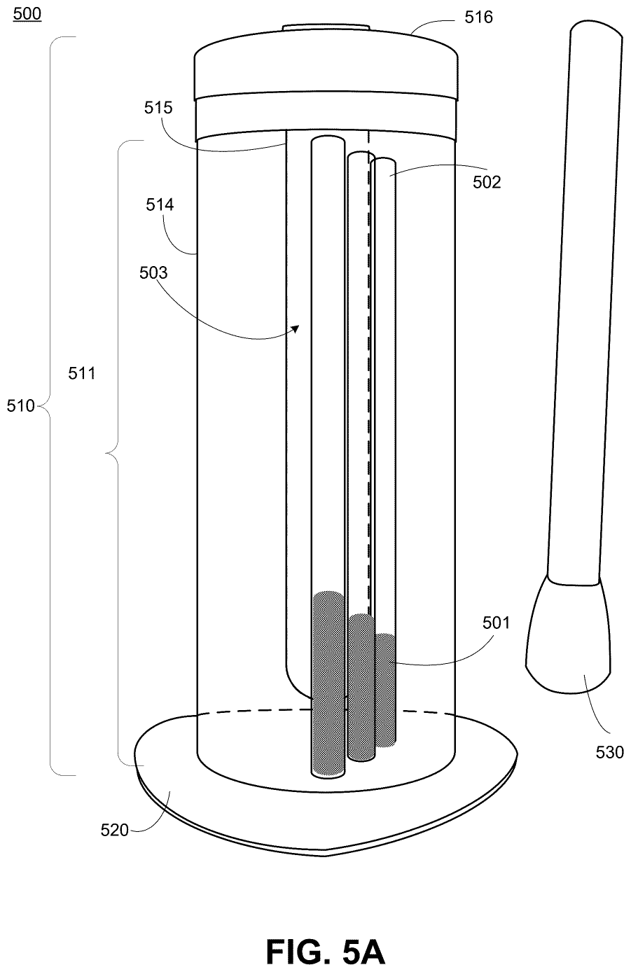

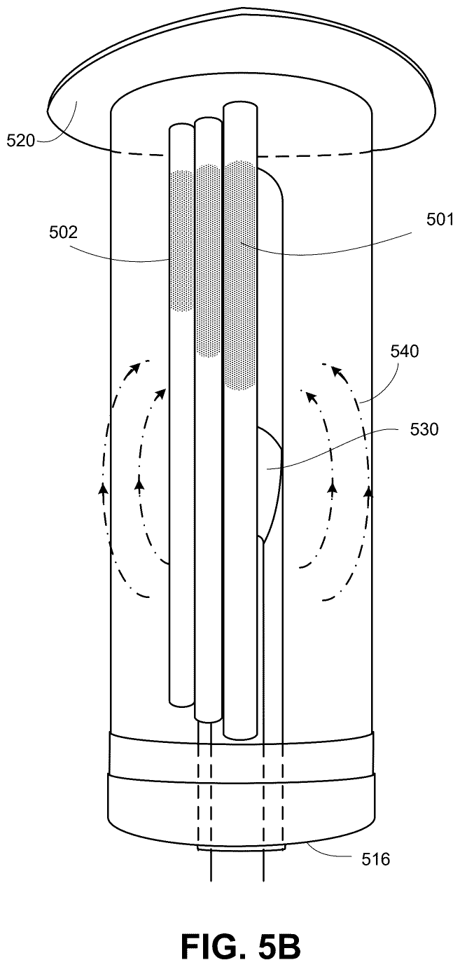

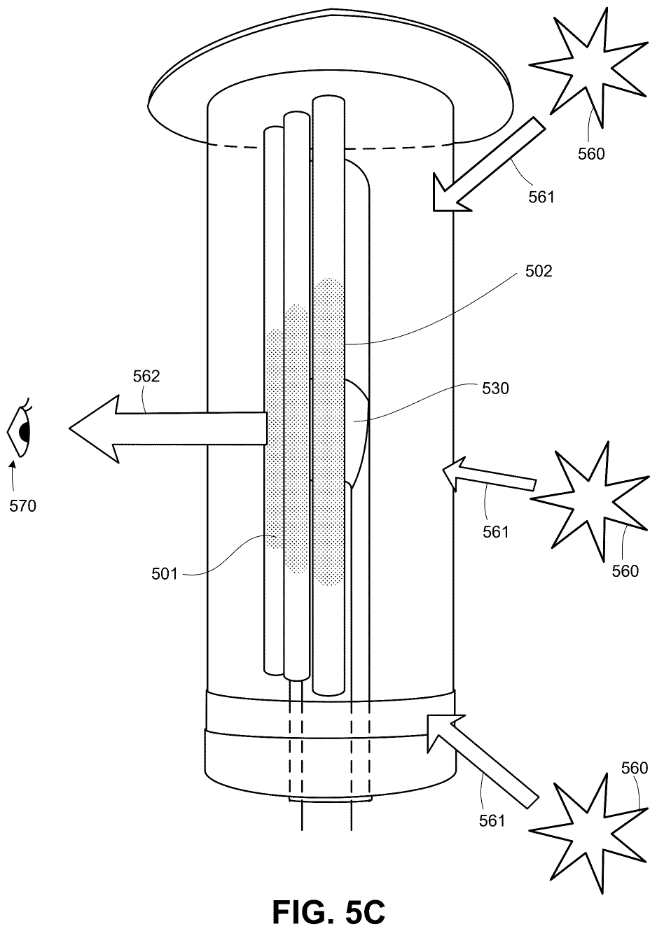

Referring now to FIGS. 5A-5C, illustrated is a 3D magnetic field visualizer 500 for visualizing three dimensions of a magnetic field using ferromagnetic particles. The disclosed embodiment beneficially allows for a polarizing screen and polarized UV light to be optional as compared to the embodiments of a 3D magnetic field visualizer described with respect to FIGS. 1A through 4.

FIG. 5A shows the visualizer 500 during an initialization or reset stage where a magnet 530 is not proximate to the fluorescent and ferrous components for visualizing the magnetic field of the magnet 530. FIGS. 5B and 5C show the visualizer 500 during a visualization stage where the magnet 530 is inserted into the visualizer 500. The following description will first describe the components of the visualizer 500 followed by an example process of resetting and using the visualizer 500.

Similar to the visualizer 100, the visualizer 500 may be a cylindrical container having fluorescent-ferrous components 501 that enable a user to visualize the lines of a magnetic field when the magnet 530 is proximate to the fluorescent-ferrous components 501. The visualizer 500 includes a container 510 and a base 520. The container 510 includes a visualization section 511. In alternative embodiments, the visualizer 500 may include a reset section that is partitioned from the visualization section 511 by a partition similar to the configuration of the visualizer 100. The container 510 has an outer wall 514, an inner wall 515, and a top surface 516. Between the outer wall 514 and the inner wall 515 is a liquid, tubes 502, and fluorescent-ferrous components 501 held within the visualization section 511. The inner wall separates a liquid held within the visualization section 511 of the container 510 from a cavity 503 in which the magnet 530 may be positioned. The refractive index of the liquid and the material of the tubes 502 may be substantially matching such that the visibility of the fluorescent-ferrous components when they fluoresce is improved.

The visualization section 511, similar to the visualization section 111, contains components for visualizing a magnetic field within the cavity 503. Components include the fluorescent-ferrous components 501 and the tubes 502. Only three tubes 502 are depicted in FIGS. 5A-5C to promote clarity for demonstrating the placement of the cavity 503 inside the visualization section 111. In some embodiments, the visualization section 511 may include a magnet (e.g., where the magnet is affixed to the visualizer rather than a separately insertable component).

While the tubes 502 may be similar in structure to the tubes 102, the fluorescent-ferrous components 501 are different from the fluorescent-ferrous components 101. Specifically, the fluorescent-ferrous components 501 are ferromagnetic particles. The particles may have an inner coating of fluorescent dye and an outer coating of a sealant that prevents degradation when the particles are suspended in the liquid within each tube 502. The sealant may be clear to allow UV light to be transmitted through the sealant, which in turn, allows the inner coating to receive the UV light and fluoresce in reaction to the UV light. The cavity 503 and the magnet 530 may be functionally and structurally similar to the cavity 103 and the magnet 130 of FIGS. 1A-1C. Although not depicted, the visualizer 500 may include a battery or a connection to an external power source. The battery or external power source may be electrically coupled to an electromagnet used during the reset stage.

During a reset or initialization stage depicted in FIG. 5A, the magnet 530 is not inserted into the visualizer 500 and the fluorescent-ferrous components 501 are located in the visualization section 511 towards the base 520 (i.e., gravity maintains the fluorescent-ferrous components 501 at the floor of the visualization section 511). In the reset stage, the visualizer 500 may be oriented either in a first orientation where the base 520 is closer to the ground or in a second orientation where the top surface 516 is closer to the ground. This description and FIG. 1A uses the first orientation in the reset stage.

During the visualization stage depicted in FIGS. 5B and 5C, the magnet 530 is inserted into the visualizer 500, the visualizer 500 is inverted (i.e., rotated 180°) with the magnet 530 inside, and the fluorescent-ferrous components 501 may engage with the magnetic field 540 of the magnet 530. In particular, after inverting the visualizer 500, gravity causes the fluorescent-ferrous components 501 to fall away from the base 520, and when the force of the magnetic field 540 of the magnet 530 exerted upon the fluorescent-ferrous components 501 is weaker than the force of gravity, the fluorescent-ferrous components 501 will continue to fall towards the top surface 516. Alternatively, when the force of the magnetic field is stronger than the force of gravity, the fluorescent-ferrous components 501 will be held aloft within the tubes 502 by the magnetic field 540.

Further during the visualization stage, one or more UV light sources 560 direct UV light 561 at the fluorescent-ferrous components 501. In response to the UV light exposure, the fluorescent-ferrous components 501 fluoresce and emit light 562. The light 562 exits the visualizer 100 through the clear exterior of the visualization section 511 and is seen by the user 570.

In some embodiments, a magnet may be inserted at a time after inverting the visualizer 500 where a portion (e.g., half) of the falling ferromagnetic particles are above a horizontal midline of the visualizer 500 and the remaining portion of the ferromagnetic particles are below the horizontal midline, but not yet contacting a bottom surface of the container. When the magnet is inserted at this time, the inserted magnet may attract both portions of the ferromagnetic particles. This timed insertion may promote a more symmetrical visualization of the magnet's entire magnetic field.

### Visualizer with Stackable Plates

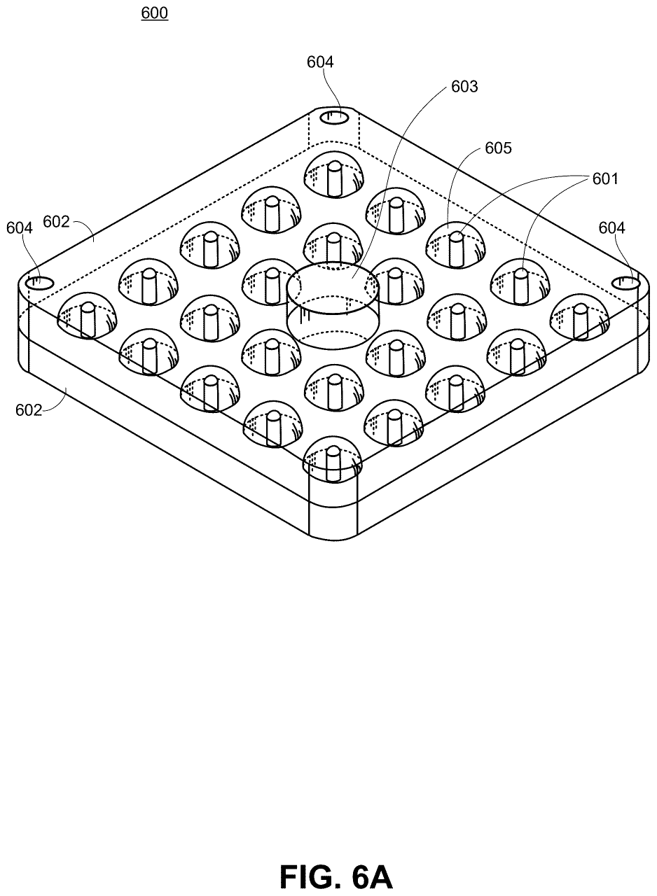

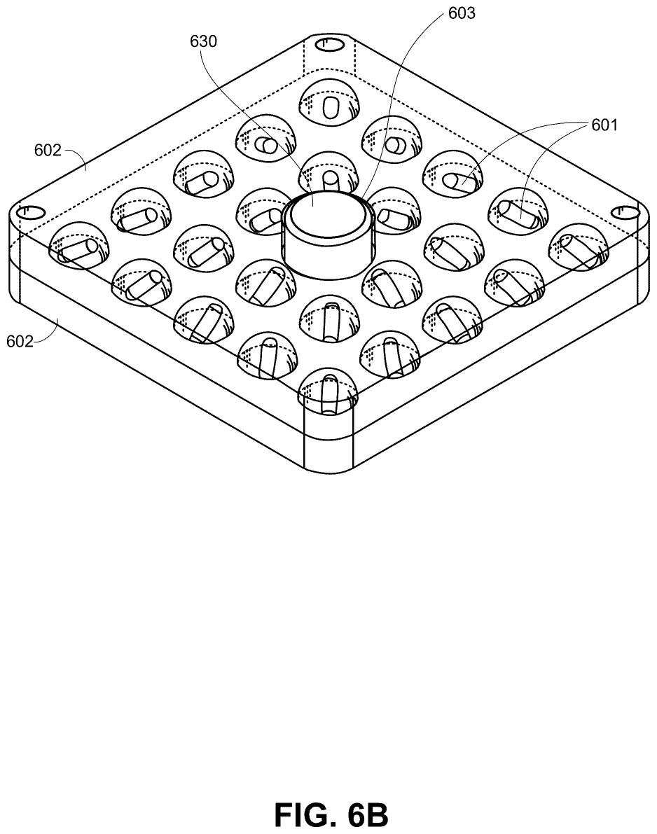

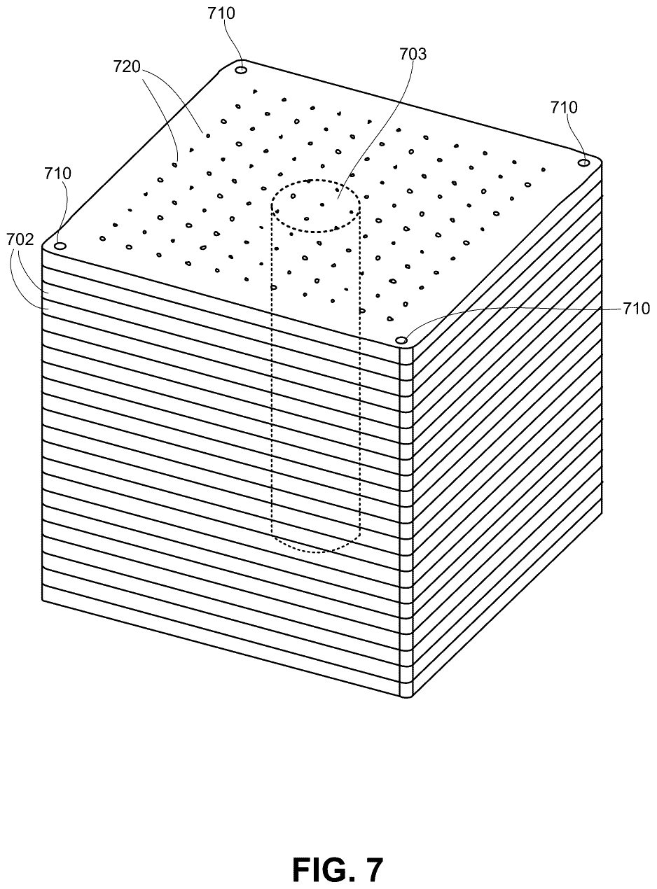

Referring now to FIGS. 6A, 6B, and 7, illustrated are stackable plates structured within a 3D magnetic field visualizer for visualizing three dimensions of a magnetic field using oblong fluorescent-ferrous components 601 within each stackable plate. Similar to the embodiment described in FIGS. 1A through 4, there are spherical shapes within which fluorescent-ferrous objects are located. Unlike the embodiment in FIGS. 1A through 4, however, the spherical shapes are formed with concave cavities inside the stackable plates, where each plate has a semispherical concave cavity 605, and two plates stacked together may form a full spherical cavity in which a fluorescent-ferrous component 601 may be located. The fluorescent-ferrous components 601 orient themselves in response to a proximate magnetic field (e.g., from a magnet within the cavity 603).

FIG. 6A shows two plates 602 of a visualizer having fluorescent-ferrous components 601 oriented along a common orientation, in accordance with one embodiment. The plates 602 may be positioned within a container of the visualizer and be encased in liquid within the container. The visualizer may incorporate more than the two plates depicted in FIG. 6A. The plates 602 may be transparent or otherwise permit light transmission. The plates 602 may have a refractive index that substantially matches (e.g., within 1% of) the refractive index of the liquid in which they are submerged. Although FIG. 6A highlights the transparency of the upper plate, such transparency may also be present in the lower plate.

A cavity 603 is located at a central region of a stack of plates. That is, one or more plates may have a through hole at its center such that, when multiple plates are stacked, the cavity 603 is formed. One of the plates that are stacked may not have a through hole at its center. For example, a plate that is at the top of the stack may not have a through hole at its center and instead, may have additional cavities for fluorescent-ferrous particles. In this example, another plate that is below the topmost plate may also not have a through hole but rather, a first surface of this plate may have concave cavities that align with the concave cavities of the topmost plate and a second surface of this plate may have a larger concave cavity whose diameter aligns with the diameter of the through holes forming the cavity 603 in plates below. That is, the second surface forms the end of the cavity 603. The cavity 603 can receive a magnet (as shown in FIG. 6B). At one or more corners of each plate, through holes 604 may be disposed, the through holes structured to receive alignment members (e.g., rods or poles) to maintain alignment of the plates when stacked. Although three through holes 604 are depicted in FIG. 6A, there may be one at each corner of the plate (i.e., four through holes). Each plate may be filled with a liquid, and each concave cavity 605 may likewise contain liquid. The liquid within the plates or concave cavities may be the same liquid in which the plates are encased.

There may be greater or fewer number of concave cavities 605 or fluorescent-ferrous components 601 than depicted in the embodiment of FIG. 6A. The fluorescent-ferrous components 601 may have an oblong, capsule-shaped, or any other suitable geometry configured to permit rotation within the corresponding concave cavity 605 or combination of two concave cavities to form a sphere-like shape. One end or portion of the fluorescent-ferrous component 601 may be coated with a ferromagnetic coating such that the fluorescent-ferrous component 601 reacts with a magnetic field at one portion and causes the fluorescent-ferrous component 601 to reorient itself based on the magnetic field.

FIG. 6B shows the two plates 602 of FIG. 6A having fluorescent-ferrous components 601 oriented along a magnetic field of a magnet 630, in accordance with one embodiment. In response to a user inserting a magnet 630 through the cavity 603, the fluorescent-ferrous components 601 may reorient themselves based on the magnetic field that interacts with the ferromagnetic coating on the fluorescent-ferrous components 601. Each fluorescent-ferrous component 601 reorients itself within the corresponding concave cavity 605 or combination of concave cavities 605 (e.g., two semispherical concave cavities of respective plates stacked together to form a sphere). Similar to the visualizer 100, the fluorescent-ferrous components 601 may be reset to return to the common orientation as depicted in FIG. 6A through one or more electromagnets. The magnet 630 may be removed from the cavity 603 so that the electromagnet(s) used for resetting may reorient the fluorescent-ferrous components 601.

FIG. 7 shows stacked plates 702 of a 3D magnetic field visualizer, in accordance with one embodiment. The plates 702 may be maintained in alignment with alignment members 710 (e.g., rods) that extend through corresponding through holes in each of the plates 702. In the center of the stacked plates 702 is a cavity 703 through which a magnet may be inserted and moved to cause the fluorescent-ferrous components in each plate to rotate. The plates 702 may be exposed to a UV light to cause the fluorescent-ferrous components to fluoresce. The plates 702 may be submerged in a liquid within a container of a visualizer, where the liquid has a refractive index that is substantially similar to (e.g., within 1% of) the refractive index of the material of the container walls and the plates such that, when UV light shines on the plates 702, a user can perceive the container walls and plates as nearly transparent while seeing the fluorescence of the fluorescent-ferrous components 601. The fluorescent-ferrous components, although not depicted in FIG. 7 for clarity, are located in each plate. The plates 702 may appear opaque as depicted in FIG. 7; however, the plates 702 may be transparent so that the fluorescent-ferrous components within may be visible.

One or more of the stacked plates 702 may include through holes 720. The through holes 720 may enable the liquid in which the stacked plates 702 are encased to travel between the plates 720, reducing hydraulic pressure from the liquid upon the stacked plates 702. For example, when submerging the stacked plates 702 inside a liquid (e.g., mineral oil), which may be the same liquid filling the concave cavities 605, the liquid exerts pressure on the plates 702 and may prevent them from maintaining contact with one another. In turn, spacing between plates 702 may cause the fluorescent-ferrous components 601 to escape the concave cavities 605. Accordingly, the through holes 720 reduce the pressure exerted by the liquid on the plates 702 and allow the plates to maintain contact with one another.

The through holes 720 may be located between concave cavities 605 (e.g., alternately disposed such that between a pair of cavities is a through hole). The locations of the through holes 720 may form a grid, one or more rings (e.g., concentric rings), or any suitable formation to promote reduction of pressure from the liquid in which the plates are encased. The diameter of each through hole 720 may be in a range within 1-2 millimeters. In some embodiments, the diameter of each through hole is approximately 1% of a length of a side of the plate 702. The diameter of each through hole may be uniform or the diameters may vary (e.g., larger diameters at through holes closer to the center of the plate 702). The number of through holes 720 may be any sufficient number to maintain contact between the plates 702 when the plates 702 are encased in the liquid.

Although not depicted in FIGS. 6A, 6B, and 7, a visualizer having plates with fluorescent-ferrous components for visualizing a magnetic field may also include a reset section and a container in which the plates may be encased in liquid. Similar to the visualizer 100, a visualizer having plates with fluorescent-ferrous components may have a top surface through which a magnet can be received in a cavity of the visualizer. The reset section may be located at the base of the visualizer. One or more electromagnets may be used to reset the fluorescent-ferrous components 601 to align in the same direction (e.g., vertically along the length of the visualizer).

### Process for Visualizing a Magnetic Field

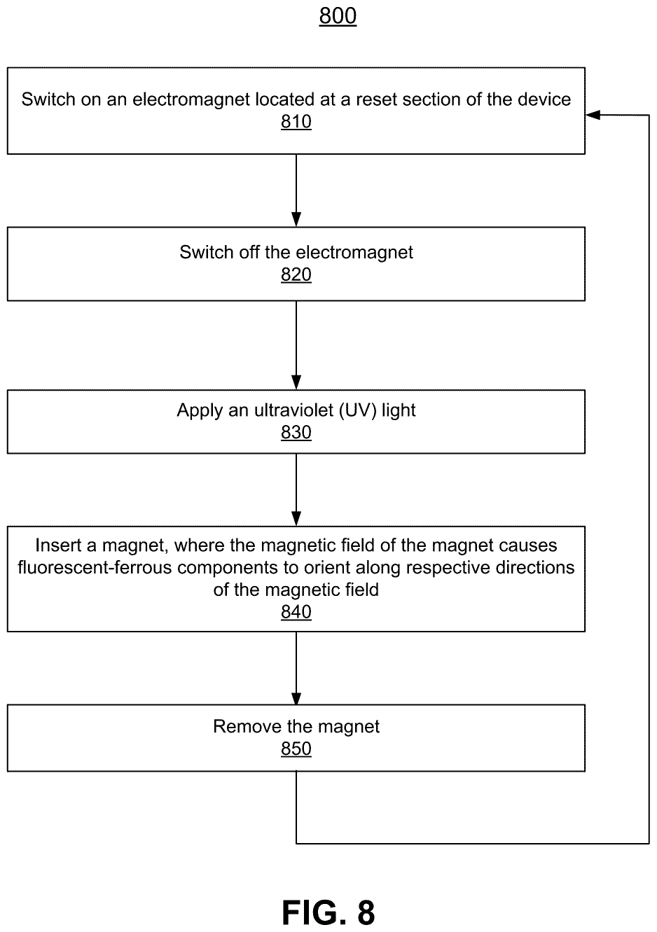

FIG. 8 is a flowchart depicting a process 800 for operating a 3D magnetic field visualizer, in accordance with one embodiment. The process 800 may be used with the visualizers depicted in FIGS. 1A-1C or FIGS. 5A-5C. The process 800 may be performed by a user (e.g., the user 170 or the user 570). The operations of the process 800 may be performed in parallel or in different orders, or different, additional, or fewer steps may be performed. For example, the switching 810 and 820 operations may be omitted when using the visualizer 500, where the force of gravity may be used to reset the fluorescent-ferrous components to the bottom of the visualizer rather than using an electromagnet. In another example, a user may insert 840 a magnet before applying 830 a UV light.

The user switches 810 on an electromagnet located at a reset section of the device. During this operation, a magnet (e.g., the magnet 130) is not engaged with the fluorescent-ferrous components such that the fluorescent-ferrous components may be reset by the electromagnet without interference from another magnet. In some embodiments, the electromagnet may be used to orient the fluorescent-ferrous components towards one direction (e.g., when using the visualizer 100). In alternative embodiments, the electromagnetic may be used to draw the fluorescent-ferrous components towards one end of the visualizer (e.g., when using the visualizer 500). The user switches 820 off the electromagnet after the fluorescent-ferrous components are reset.

The user applies 830 a UV light to the visualizer and inserts 840 a magnet into the visualizer (i.e., into the cavity surrounded by tubes containing the fluorescent-ferrous components). The magnetic field of the inserted magnet causes the fluorescent-ferrous components to orient along the directions of the magnetic field. For example, the fluorescent-ferrous components 501 of the visualizer 500 are oriented to surround the magnet 530 when the magnetic field of the magnet 530 is strong enough to hold them aloft within each tube. In another example, the fluorescent-ferrous components 101 of the visualizer 100 rotate such that the ferrous rod within each fluorescent-ferrous component 101 is aligned to a magnetic field line of the magnetic 130. The UV light applied 830 to the oriented fluorescent-ferrous components provides the user with a glowing visual of the magnetic field of the magnet within the visualizer. Once the user removes 850 the magnet, the UV light can be removed or switched off until the user has reset the visualizer (e.g., performed the operations of switching 810 on the electromagnet and switching 820 off the electromagnet).

### Additional Configuration Considerations

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Where values are described as “approximate” or “substantially” (or their derivatives), such values should be construed as accurate +/−10% unless another meaning is apparent from the context. For example, “approximately ten” should be understood to mean “in a range from nine to eleven.” In another example, “substantially the same direction” should be understood to mean aligned in a direction or within +/−10 degrees from that direction.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for a system and a process for visualizing a magnetic field in three dimensions through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. A device for visualizing a magnetic field, the device comprising:
a top surface;
an outer wall and an inner wall connected to the top surface, wherein the outer wall is clear;
a partition connected to the outer wall and the inner wall, wherein a visualization section is bounded by one side of the partition; and
a cavity enclosed by the inner wall, wherein an opening of the cavity is located through the top surface, the opening configured to receive a magnet;
wherein the visualization section is sealed and comprises:
containers that each contain fluorescent-ferrous components, and
a liquid encasing the containers; and
wherein the outer wall, the containers, and the liquid have substantially identical refractive indices for light generated by the fluorescent-ferrous components.

2. The device of claim 1, wherein the partition separates the visualization section from a reset section comprising an electromagnet configured to orient the fluorescent-ferrous components towards one direction in response to the electromagnet being switched on.

3. The device of claim 1, wherein the magnetic field of the magnet causes the fluorescent-ferrous components to orient along respective directions of the magnetic field.

4. The device of claim 1, wherein the containers are clear plates, each clear plate including a plurality of through-holes and an array of concave cavities, each concave cavity structured to receive a fluorescent-ferrous component, and each through-hole structured to receive an alignment member to maintain alignment of the clear plates when stacked.

5. The device of claim 1, wherein the containers are clear tubes, one end of each clear tube contacting the partition, and wherein the fluorescent-ferrous components are beads, wherein each bead is clear, each bead has substantially identical refractive index to the liquid for light generated by the fluorescent-ferrous components and houses a fluorescent rod with a ferromagnetic tip.

6. The device of claim 5, wherein each bead has a diameter of 0.01 millimeters (mm) to 2 mm.

7. The device of claim 5, wherein the beads are composed of one of a borosilicate or polyacrylate.

8. The device of claim 5, wherein the beads fill the clear tubes such that they are substantially contiguous to one another.

9. The device of claim 5, wherein the magnetic tip comprises a ferromagnetic ball.

10. The device of claim 5, wherein each fluorescent rod is a clear rod coated with fluorescent pigment that fluoresces when exposed to UV light.

11. The device of claim 5, wherein the outer wall is divided into sections and a polarized screen is attached to one section, the polarized screen configured to filter out polarized UV light that reacts with the fluorescent rods and pass through fluorescent light produced by the fluorescent rods.

12. The device of claim 11, further comprising one or more polarized ultraviolet (UV) light sources.

13. The device of claim 5, wherein the clear tubes are composed of one of a borosilicate or polyacrylate.

14. The device of claim 5, wherein the fluorescent-ferrous components are ferromagnetic particles having an outer coating of a clear sealant and an inner coating of a fluorescent pigment.

15. The device of claim 5, wherein each clear tube has a diameter of 0.1 mm to 3 mm.

16. The device of claim 5, wherein the clear tubes are positioned substantially contiguous to one another.

17. The device of claim 5, wherein at least one of the clear tubes contacts the inner wall.

18. A method for visualizing a magnetic field, the method comprising:
applying an ultraviolet (UV) light to a device comprising:
a top surface;
an outer wall and an inner wall connected to the top surface, wherein the outer wall is clear;
a partition connected to the outer wall and the inner wall, wherein the partition separates a visualization section from a reset section; and
a cavity enclosed by the inner wall, wherein an opening of the cavity is located through top surface, the opening configured to receive a magnet;
wherein the visualization section is sealed and further comprises:
containers, wherein each container contains fluorescent-ferrous components, and
a liquid encasing the containers; and
wherein the reset section comprises an electromagnet configured to orient the fluorescent-ferrous components towards one direction in response to the electromagnet being switched on; and
wherein the outer wall, the containers, and the liquid have substantially identical refractive indices for light generated by the fluorescent-ferrous components; and
inserting a magnet into the cavity of the device, wherein the magnetic field of the magnet causes the fluorescent-ferrous components to orient along respective directions of the magnetic field.

19. The method of claim 18, further comprising:
switching on the electromagnet to orient the fluorescent-ferrous components towards one direction; and
switching off the electromagnet while the magnet is inserted into the cavity.

20. The method of claim 18, wherein the fluorescent-ferrous components are beads composed of one of a borosilicate or polyacrylate, each bead is clear and houses a fluorescent rod with a magnetic tip, and the UV light is polarized.
